(19) United States
(12) Patent Application Publication
(10) Pub. No.: US 2018/0307377 A1
(43) Pub. Date: Oct. 25, 2018

(54) TOUCH SUBSTRATE AND TOUCH DISPLAY DEVICE

(71) Applicant: BOE TECHNOLOGY GROUP CO., LTD., Beijing (CN)

(72) Inventor: Hongfei CHENG, Beijing (CN)

(73) Assignee: BOE TECHNOLOGY GROUP CO., LTD., Beijing (CN)

(21) Appl. No.: 15/560,036

(22) PCT Filed: Mar. 16, 2017
(86) PCT No.: PCT/CN2017/076918

§ 371 Date: Sep. 20, 2017

(30) Foreign Application Priority Data
Aug. 11, 2016 (CN) 201610659020.9

(51) Int. Cl. G06F 3/042; H01L 25/16; H01L 27/146

(52) U.S. Cl. CPC G06F 3/0421; G06F 3/0425; G06F 2203/04102; H01L 27/14643; H01L 25/167

(57) ABSTRACT

A touch substrate and a touch display device are provided. The touch substrate includes: a light source; a light transmission plate on a light output side of the light source; a flexible substrate including a flexible base and a plurality of contact portions provided on the flexible base and facing the light transmission plate; and a light detecting device, configured to detect emergent light output from the light transmission plate. The flexible base is provided opposite to the light transmission plate, so that a transparent spacer layer is provided therebetween, a refractive index of the transparent spacer layer is smaller than a refractive index of the light transmission plate, and a distance from the flexible base to the light transmission plate is larger than a height of the contact portion

### TECHNICAL FIELD

Embodiments of the present disclosure relate to a touch substrate and a touch display device.

### BACKGROUND

At present, a touch technology has been widely used in a mobile phone, a tablet personal computer, and other electronic apparatuses. The touch technology provides an highly efficient and convenient mode of human-computer interaction, and a basic principle thereof is to capture touch and action information of a touch object (for example, a finger or a stylus pen) as a starting point, transform the touch and the action information acquired as an electrical signal for determination and identification, so as to implement a control function.

In addition, in a field of the touch technology, a touch screen comprises a resistive type, a capacitive type, a light-sensitive type, and many other types. A light-sensitive touch screen senses change in light caused by a touch operation by using a photodetector, to determine a position of the touch operation.

### SUMMARY

Embodiments of the disclosure provide a touch substrate and a touch display device.

At least one of the embodiments provides a touch substrate, comprising: a light source; a light transmission plate, on a light output side of the light source; a flexible substrate, comprising a flexible base and a plurality of contact portions provided on the flexible base and facing the light transmission plate, wherein the flexible base is opposite to the light transmission plate, and a transparent spacer layer is between the flexible base and the light transmission plate, a refractive index of the transparent spacer layer is smaller than a refractive index of the light transmission plate, and a distance from the flexible base to the light transmission plate is larger than a height of the contact portion; and a light detecting device, configured to detect an output light output from the light transmission plate.

As an example, the light detecting device is on a side of the contact portion away from the light transmission plate.

As an example, the light detecting device comprises a plurality of sub-detecting devices, the plurality of sub-detecting devices are between the plurality of contact portions and the flexible base respectively.

As an example, the plurality of sub-detecting devices are photodiodes or phototriodes.

As an example, the light detecting device is on a side of the flexible base away from the contact portion.

As an example, the plurality of contact portions are oblique with respect to the flexible base.

As an example, the light detecting device is a camera.

As an example, the light detecting device is on a side of the light transmission plate away from the contact portion.

As an example, the light detecting device is a camera, or a photodiode array, or a phototriode array.

As an example, the touch substrate further comprises a reflective layer, wherein the reflective layer is between the plurality of contact portions and the flexible base.

As an example, the reflective layer comprises a plurality of reflecting portions, and the plurality of reflecting portions respectively correspond to the plurality of contact portions.

As an example, the touch substrate further comprises a support portion, located between the light transmission plate and the flexible substrate, so that the light transmission plate and the flexible substrate are connected with each other.

As an example, the touch substrate further comprises a spacer, wherein the spacer is inside the support portion and is between the flexible base and the light transmission plate, and a height of the spacer is equal to a distance from the flexible base to the light transmission plate.

As an example, the spacer is light blocking.

As an example, the plurality of contact portions are light-transmissive.

As an example, a side surface of the contact portion is a reflecting surface.

At least one of the embodiments provides a touch display device, comprising any one of the afore-mentioned touch substrate.

As an example, the touch display device further comprises a display panel, wherein the touch substrate is on a light output side of the display panel, and the light transmission plate is between the flexible substrate and the display panel.

As an example, the touch display device further comprises an array substrate, wherein the touch substrate is opposite to the array substrate, and the light transmission plate is between the flexible substrate and the array substrate.

As an example, the touch display device further comprises a backlight source and a light guiding element, wherein the light guiding element is configured to guide light output from a side surface of the light transmission plate of the touch substrate into the backlight source.

A light-sensitive touch technology is used in embodiments of the present disclosure, which, as compared with a resistive touch technology or a capacitive touch technology, can implement a large-sized touch application more easily; on the other hand, the embodiment of the present disclosure may also be used in a flexible display device.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematically cross-sectional view of a touch substrate provided by an embodiment of the present disclosure;

FIG. 2 is a schematically cross-sectional view of a touch substrate in a touch state provided by an embodiment of the present disclosure;

FIG. 3a is a schematically cross-sectional view of a touch substrate comprising a plurality of sub-detecting devices provided by an embodiment of the present disclosure;

FIG. 3b is a schematically cross-sectional view of the touch substrate in the touch state of FIG. 3a;

FIG. 4a is a schematically cross-sectional view of a touch substrate comprising a reflective layer provided by an embodiment of the present disclosure;

FIG. 4b is a schematically cross-sectional view of the touch substrate in the touch state of FIG. 4a;

FIG. 5 is a top-view schematic diagram of a touch substrate in a touch state provided by an embodiment of the present disclosure;

FIG. 6 is a schematically cross-sectional view of a touch substrate comprising a spacer provided by an embodiment of the present disclosure;

FIG. 7a is a schematically cross-sectional view of an on-cell touch display device provided by an embodiment of the present disclosure;

FIG. 7b is a schematically cross-sectional view of an in-cell touch display device provided by an embodiment of the present disclosure;

FIG. 8 is a schematic diagram of a touch display device comprising a backlight source and a light guiding element provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “comprises,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “right,” “left” and the like are only used to indicate relative position relationship, and when the position of the object which is described is changed, the relative position relationship may be changed accordingly.

Embodiments of the present disclosure provide a touch substrate and a touch display device, which brings a contact portion into contact with a light transmission plate during a touch operation, so that a total reflection state of light at an interface of the light transmission plate is varied. Because the light emitted from the light transmission plate is changed, and then a touch position can be determined by detecting the light. Since a light-sensitive touch technology is used in the embodiments of the present disclosure, which, as compared with a resistive touch technology or a capacitive touch technology, can implement a large-sized touch application more easily; on the other hand, since the contact portion is provided on a flexible base, the embodiments of the present disclosure can also be used in a flexible display device.

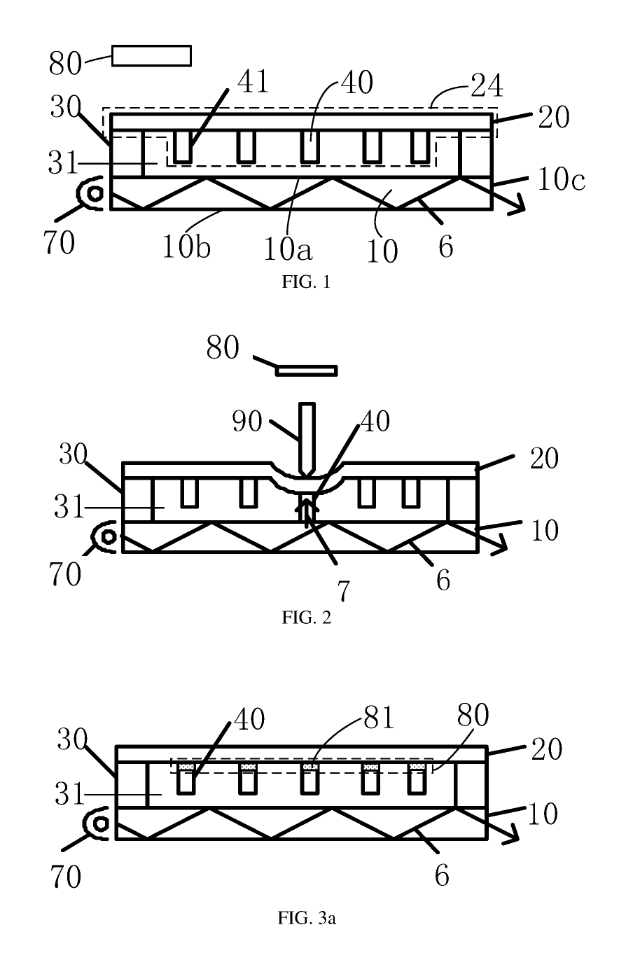

At least one embodiment of the present disclosure provides a touch substrate. As illustrated in FIG. 1, the touch substrate comprises: a light source 70; a light transmission plate 10, disposed at light output side of the light source 70; a support portion 30 (for example, a frame sealant or the like), disposed on the light transmission plate 10; a flexible substrate 24, disposed on a side of the support portion 30 away from the light transmission plate 10, the flexible substrate 24 comprises a flexible base 20 and a plurality of contact portions 40 provided on the flexible base 20, the plurality of contact portions 40 face the light transmission plate 10; and a light detecting device 80, configured to detect emergent light output from the light transmission plate 10.

In the embodiment of the present disclosure, the flexible base 20 and the light transmission plate 10 are provided opposite to each other so as to form a transparent spacer layer 31 therebetween, a refractive index of the transparent spacer layer 31 is smaller than a refractive index of the light transmission plate 10. When a comprised angle between the light 6, which is emitted by the light source 70 and enters the light transmission plate 10, and an upper surface 10a of the transmission plate 10 is larger than or equal to a critical angle of total reflection, the light 6 is subjected to the total reflection at the upper surface 10a. For example, the transparent spacer layer 31 is provided therein with air or other fluid (e.g., a gas or a liquid). Once the flexible base 20 is touched, the contact portion 40 moves within the transparent spacer layer 31.

In the embodiment of the present disclosure, a distance from the flexible base 20 to the light transmission plate 10 is larger than a height of the contact portion 40. In a case where the flexible base 20 is not touched, the contact portion 40 and the light transmission plate 10 are arranged spaced apart from each other. The flexible base 20 is flexible, for example, the flexible base 20 is made of polyethylene, polycarbonate, polyethylene terephthalate (PET) or a similar flexible material. In this case, when the flexible base 20 is being touched, the contact portion 40 is brought into contact with the light transmission plate 10, so as to change the total reflection state of the light 6 at the upper surface 10a of the light transmission plate 10.

For example, air, or a thin film having a refractive index smaller than that of the light transmission plate 10 is provided beneath the lower side of the light transmission plate 10 (i.e., the side away from the transparent spacer layer 31), so that the light 6 is subjected to the total reflection at a lower surface 10b of the light transmission plate 10. Alternatively, the lower surface 10b of the light transmission plate 10 is a reflecting surface (for example, a reflective material is applied on the lower surface 10b or a reflective layer is provided on the lower surface 10b), so that the light 6 is subjected to mirror reflection at the lower surface 10b. The light 6 is subjected to the total reflection at the upper surface 10a of the light transmission plate 10, or is subjected to the total reflection or mirror reflection at the lower surface 10b, so that the light 6 can be propagated within the light transmission plate 10.

For example, the light detecting device 80 is provided on a side of the contact portion 40 away from the light transmission plate 10, in which case, the light detecting device 80 can detect emergent light output from the upper surface 10a of the light transmission plate 10 to determine the touch position. Alternatively, the light detecting device 80 is provided on a side of the light transmission plate 10 away from the contact portion 40, in which case, the light detecting device 80 can detect emergent light output from the lower surface 10b of the light transmission plate 10 to determine the touch position. Alternatively, the light detecting device 80 is provided at a lateral side of the light transmission plate 10 (a right side of the light transmission plate 10 illustrated in FIG. 1), in which case, the light detecting device 80 may detect emergent light output from a side surface 10c of the light transmission plate 10 to determine the touch position.

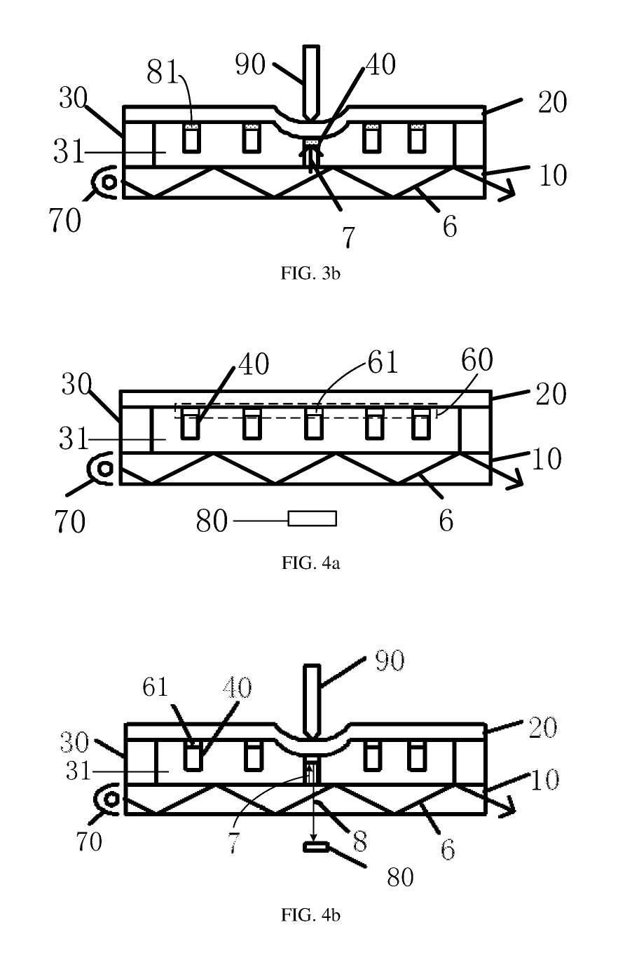

Hereinafter, an embodiment in which a light detecting device 80 is provided on one side of a contact portion 40 away from a light transmission plate 10 will be described, in conjunction with FIG. 2 and FIG. 3a to FIG. 3b.

For example, in at least one of embodiments of the present disclosure, as illustrated in FIG. 2, the light detecting device 80 is provided on one side of a flexible base 20 away from the contact portion 40. In a case where the flexible base 20 is touched (by a stylus pen 90, for example), the flexible base 20 becomes bent and the contact portion 40 at a touched position is brought into contact with the light transmission plate 10. In this case, a total reflection condition of the upper surface 10a of the light transmission plate 10 at the touch position is failed, so that a portion of a light 6, which should have been propagated within the light transmission plate 10, is emitted from the touch position toward the contact portion 40 to form emergent light 7. The emergent light 7 enters the contact portion 40 and then is output from the flexible base 20. In this way, the light detecting device 80 can determine the touch position by detecting a position of light leakage (i.e., a position where the emergent light 7 is output).

For example, the light detecting device 80 is a camera, which captures an image of the flexible base 20, so that the touch position is determined according to a position of a light spot in a captured image. For example, the light detecting device 80 is the camera, and the light detecting device 80 is provided at a frame region of the touch substrate, so as to avoid shielding a screen of the touch substrate.

For example, in a case where the light detecting device 80 is provided on one side of the flexible base 20 away from the contact portion 40, the contact portion 40 is disposed obliquely with respect to the flexible base 20. Since the emergent light 7 is output along an extending direction of the contact portion 40, the emergent light 7 can be prevented from being shielded by the stylus pen 90, which may result in a decrease in a touch effect, by disposing the contact portion 40 obliquely with respect to the flexible base 20.

For example, in at least one of embodiments of the present disclosure, a light detecting device 80 is provided on one side of a flexible base 20 away from the contact portion 40, as illustrated in FIG. 3a. The light detecting device 80 comprises a plurality of sub-detecting devices 81, the plurality of sub-detecting devices 81 respectively correspond to the above-described plurality of contact portions 40 (as illustrated in FIG. 3a, each sub-detecting device 81 corresponding to one of the contact portions 40), and the plurality of sub-detecting devices 81 are provided between the contact portion 40 and the flexible base 20. In this embodiment, since the sub-detecting device 81 is provided between the contact portion 40 and the flexible base 20, it will not be shielded by a touch object during touch operation, so that a touch effect is better.

In the embodiment, in a case where the flexible base 20 illustrated in FIG. 3a is bent by being touched, the contact portion 40 at the touch position is brought into contact with the light transmission plate 10, as illustrated in FIG. 3b, so that the light transmission plate 10 transmits emergent light 7 at the touch position. The emergent light 7 enters the contact portion 40 and is detected by a corresponding sub-detecting device 81, and then the touch position is determined according to a position of the sub-detecting device 81.

For example, the sub-detecting device 81 is a photodiode or a phototriode (e.g., a photosensitive thin film transistor).

Hereinafter, an embodiment in which a light detecting device 80 is provided on one side of a light transmission plate 10 away from a contact portion 40 will be described, in conjunction with FIG. 4a and FIG. 4b.

For example, as illustrated in FIG. 4a, the light detecting device 80 is provided on one side of the light transmission plate 10 away from the contact portion 40, and a touch substrate provided by at least one of embodiments of the present disclosure further comprises a reflective layer 60, the reflective layer 60 being provided between the contact portion 40 and the flexible base 20. As illustrated in FIG. 4b, a flexible base 20 is bent by touching, the contact portion 40 at the touch position is brought into contact with the light transmission plate 10, so that the light transmission plate 10 emits emergent light 7 at the touch position. The emergent light 7 enters the contact portion 40 and is reflected by the reflective layer 60, and then enters the light transmission plate 10 again. After that, emergent light 8 is emitted from a lower surface of the light transmission plate 10, and the emergent light 8 is detected by the light detecting device 80, so that the touch position is determined.

For example, the reflective layer 60 comprises a plurality of reflecting portions 61 spaced apart from each other, and the plurality of reflecting portions 61 respectively correspond to a plurality of contact portions 40 (as illustrated in FIG. 4a and FIG. 4b, each reflecting portion 61 corresponds to one of contact portions 40). By providing the plurality of reflecting portions 61 spaced apart from each other, when the touch substrate provided by the embodiment of the present disclosure is provided on a light output side of a display panel to form a touch display device, it is possible to effectively avoid the reflective layer 60 from affecting a display effect.

For example, the light detecting device 80 is a camera, or a photodiode array, or a phototriode (e.g., a photosensitive thin film transistor) array. In a case where the light detecting device 80 is the camera, a lower side of the light transmission plate 10 is captured by the light detecting device 80, and the touch position is determined according to a position of a light spot in a captured image; and in a case where the light detecting device is the photodiode array or the phototriode array, the touch position is determined according to a position of the photodiode or the phototriode at the touch position.

In the above-described embodiments illustrated in FIG. 2 to FIG. 4b, by detecting the emergent light output from the upper surface or the lower surface of the light transmission plate 10 to determine the touch position, multi-touch may be implemented.

In the above-described embodiments illustrated in FIG. 2 to FIG. 4b, for example, the contact portion 40 is light-transmissive, so that the emergent light 7 is obtained by outputting the light 6 from the upper surface of the light transmission plate 10, and then the emergent light 7 enters the contact portion 40. In this way, the light detecting device 80 can detect the emergent light 7 (with reference to FIG. 2 or FIG. 3b) or detect the reflected light of the emergent light 7 (with reference to FIG. 4b).

For example, in a case where the contact portion 40 is light-transmissive, a side surface 41 (with reference to FIG. 1) of the contact portion 40 is provided with a reflecting surface, for example, the reflecting surface is formed by coating a reflective material or providing a reflective layer on the side surface 41 of the contact portion 40. By providing the reflecting surface on the side surface 41 of the contact portion 40, the light emitted from the light transmission plate 10 can be propagated within the contact portion 40 and cannot exit from the side surface 41 of the contact portion 40, thereby improving the touch effect.

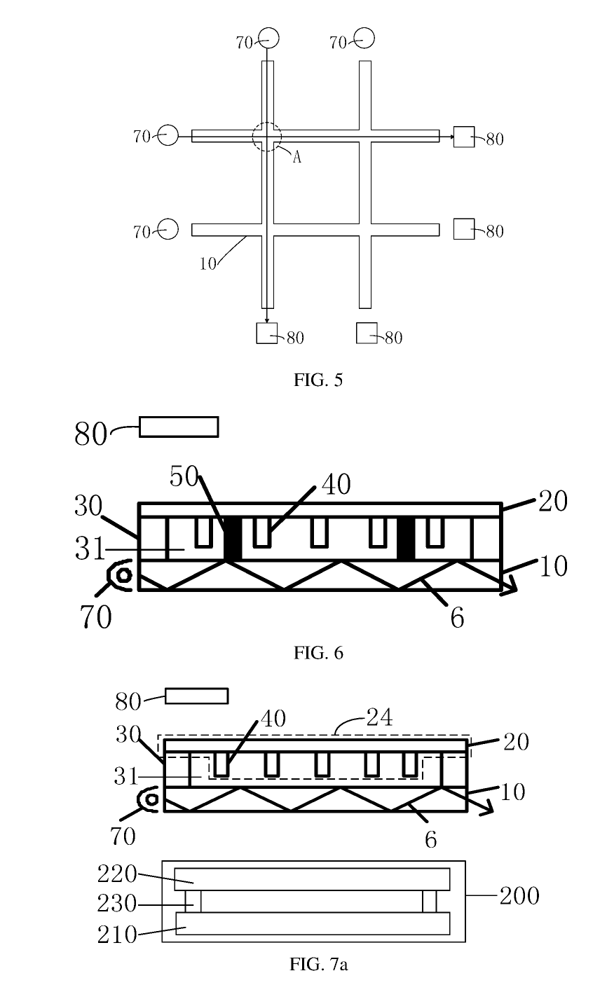

Hereinafter, an embodiment in which a light detecting device 80 is provided at a lateral side of a light transmission plate 10 will be described in conjunction with FIG. 5.

For example, as illustrated in FIG. 5, the light transmission plate 10 has a grid-like structure, the grid-like structure comprises a plurality of laterally extending portions and a plurality of longitudinally extending portions. One of side ends of each laterally extending portion is provided with a light source 70, and the other side end is provided with a light detecting device 80. Similarly, One of side ends of each longitudinally extending portion is provided with a light source 70, and the other side end is provided with a light detecting device 80. With reference to a touch position A in FIG. 5, if the touch operation occurs, the light in the light transmission plate 10 is output from the touch position A, thus the intensity of the emergent light output from the side ends of both the laterally extending portion and the longitudinally extending portion is decreased, therefore, a horizontal ordinate of the touch position A can be obtained according to the light detecting device 80 corresponding to the laterally extending portion, and a vertical ordinate of the touch position A can be obtained according to the light detecting device 80 corresponding to the longitudinally extending portion, thereby obtaining coordinates of the touch position A.

It should be noted that, in the embodiment illustrated in FIG. 5, the contact portion 40 may be transparent (i.e., light-transmissive), and may also be opaque (i.e., light-blocking), as long as the light detecting device 80 is capable of detecting the variation of the intensity of the emergent light output from the side end of the light transmission plate 10.

For example, as illustrated in FIG. 6, a touch substrate provided by at least one of embodiments of the present disclosure further comprises a spacer 50, the spacer 50 being provided inside a support portion 30 and positioned between a flexible base 20 and a light transmission plate 10. For example, a height of the spacer 50 being equal to a distance from the flexible base 20 to the light transmission plate 10. By providing the spacer 50, the flexible substrate 20 can be prevented from being brought into contact with the light transmission plate 10 at a middle position of the touch substrate due to its own gravitational influence.

For example, the spacer 50 is opaque, and for example, it is made from black opaque material, (e.g., a black resin). In this case, when light output from the upper surface of the light transmission plate 10 incidents on the spacer 50, the light is absorbed by the spacer 50, so that it is possible to avoid the effect on the direction of the emergent light caused by the spacer 50, and in turns avoid the interference on touch positioning.

For example, in at least one of embodiments of the present disclosure, the light source 70 is an infrared light source, and accordingly, the light detecting device 80 is an infrared ray detector. In a case where the touch substrate provided by the embodiment of the present disclosure is used in a display device, by using the infrared light source and the infrared ray detector, it is possible to avoid the interference of light emitted by other light sources (e.g., a backlight source in a liquid crystal display device or a light-emitting element in an active light-emitting device) in the display device and received by the light detecting device 80. It can be contemplated that the light source 70 may be other light sources emitting light of a preset wavelength, and accordingly, the light detecting device 80 is configured to sense the light of the preset wavelength.

At least one of embodiments of the present disclosure further provides a touch display device, comprising the touch substrate provided by any one of the above-described embodiments of the present disclosure.

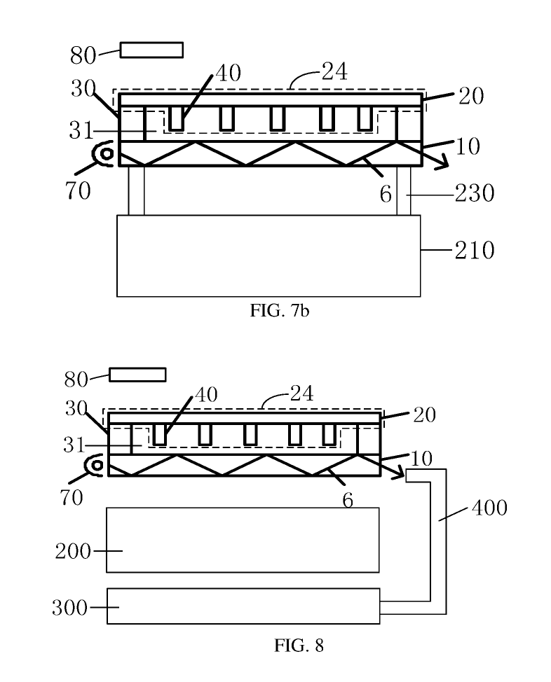

For example, the touch display device is an on-cell touch display device. For example, as illustrated in FIG. 7a, the touch display device further comprises a display panel 200, the above-described touch substrate being provided on a light output side of the display panel 200, and a light transmission plate 10 being provided between a flexible substrate 24 and the display panel 200.

For example, the display panel 200 comprises an array substrate 210 and an opposed substrate 220, as well as a connection portion 230 connecting the two substrates. For example, the display panel 200 is a liquid crystal panel, in which case, a liquid crystal layer is provided between the array substrate 210 and the opposed substrate 220, and the array substrate 210 is provided thereon with pixel electrodes arranged in a matrix. For example, the display panel 200 may also be an organic light-emitting diode (OLED), in which case, the array substrate 210 is provided thereon with OLEDs arranged in a matrix.

For example, the touch display device provided by at least one of embodiments of the present disclosure is an in-cell touch display device. For example, as illustrated in FIG. 7b, the touch display device further comprises the array substrate 210, the above-described touch substrate is provided opposite to the array substrate 210 (that is to say, the touch substrate is used as an opposed substrate of the display panel), and the light transmission plate 10 is provided between the flexible substrate 24 and the array substrate 210.

For example, as illustrated in FIG. 8, the touch display device further comprises a backlight source 300 and a light guiding element 400 (e.g., an optical fiber), and the light guiding element 400 is configured to guide the light output from a side surface of the light transmission plate 10 of the touch substrate (with reference to 10c in FIG. 1) into the backlight source 300. Thus, it is possible to sufficiently utilize light emitted from the light source of the touch substrate, to improve an integration degree of the touch display device.

The touch display device provided by the embodiment of the present disclosure may be any product or part with a display function, such as a liquid crystal display device, electronic paper, an OLED display device, a mobile phone, a tablet personal computer, a television, a monitor, a laptop computer, a digital photo frame and a navigator.

The touch substrate and touch display device according to the above-described embodiments may be referred to each other. In addition, without conflict, the embodiments of the present disclosure and features in the embodiments may be combined with each other.

The foregoing embodiments merely are exemplary embodiments of the present disclosure, and not intended to define the scope of the present disclosure, and the scope of the present disclosure is determined by the appended claims.

The present application claims priority of Chinese Patent Application No. 201610659020.9 filed on Aug. 11, 2016, the present disclosure of which is incorporated herein by reference in its entirety as part of the present application.

1. A touch substrate, comprising:
a light source;
a light transmission plate, on a light output side of the light source;
a flexible substrate, comprising a flexible base and a plurality of contact portions provided on the flexible base and facing the light transmission plate, wherein the flexible base is opposite to the light transmission plate, and a transparent spacer layer is between the flexible base and the light transmission plate, a refractive index of the transparent spacer layer is smaller than a refractive index of the light transmission plate, and a distance from the flexible base to the light transmission plate is larger than a height of the contact portion; and
a light detecting device, configured to detect an output light output from the light transmission plate.

2. The touch substrate according to claim 1, wherein the light detecting device is on a side of the contact portion away from the light transmission plate.

3. The touch substrate according to claim 2, wherein the light detecting device comprises a plurality of sub-detecting devices, the plurality of sub-detecting devices are between the plurality of contact portions and the flexible base respectively.

4. The touch substrate according to claim 3, wherein the plurality of sub-detecting devices are photodiodes or phototriodes.

5. The touch substrate according to claim 2, wherein the light detecting device is on a side of the flexible base away from the contact portion.

6. The touch substrate according to claim 5, wherein the plurality of contact portions are oblique with respect to the flexible base.

7. The touch substrate according to claim 5, wherein the light detecting device is a camera.

8. The touch substrate according to claim 1, wherein the light detecting device is on a side of the light transmission plate away from the contact portion.

9. The touch substrate according to claim 8, wherein the light detecting device is a camera, or a photodiode array, or a phototriode array.

10. The touch substrate according to claim 8, further comprising a reflective layer, wherein the reflective layer is between the plurality of contact portions and the flexible base.

11. The touch substrate according to claim 10, wherein the reflective layer comprises a plurality of reflecting portions, and the plurality of reflecting portions respectively correspond to the plurality of contact portions.

12. The touch substrate according to claim 1, further comprising a support portion, located between the light transmission plate and the flexible substrate, so that the light transmission plate and the flexible substrate are connected with each other.

13. The touch substrate according to claim 12, further comprising a spacer, wherein the spacer is inside the support portion and is between the flexible base and the light transmission plate, and a height of the spacer is equal to a distance from the flexible base to the light transmission plate.

14. The touch substrate according to claim 13, wherein the spacer is light blocking.

15. The touch substrate according to claim 1, wherein the plurality of contact portions are light-transmissive.

16. The touch substrate according to claim 15, wherein a side surface of the contact portion is a reflecting surface.

17. A touch display device, comprising the touch substrate according to claim 1.

18. The touch display device according to claim 17, further comprising a display panel, wherein the touch substrate is on a light output side of the display panel, and the light transmission plate is between the flexible substrate and the display panel.

19. The touch display device according to claim 17, further comprising an array substrate, wherein the touch substrate is opposite to the array substrate, and the light transmission plate is between the flexible substrate and the array substrate.

20. The touch display device according to claim 17, further comprising a backlight source and a light guiding element, wherein the light guiding element is configured to guide light output from a side surface of the light transmission plate of the touch substrate into the backlight source.
